(19) United States
(12) Patent Application Publication
(10) Pub. No.: US 2025/0364220 A1
(43) Pub. Date: Nov. 27, 2025

(54) BILAYER PLASMA OXIDATION PROCESSES

(71) Applicant: Applied Materials, Inc., Santa Clara, CA (US)

(72) Inventors: Dileep Venkata Sai VADLADI, Sunnyvale, CA (US); Dimitrios PAVLOPOULOS, Glendale, CA (US); Wei LIU, San Jose, CA (US); Moon Hee SEO, Santa Clara, CA (US); Jae Young PARK, Sunnyvale, CA (US); Amit JAIN, Mountain View, CA (US); Minghang LI, Fremont, CA (US); Sahil TAHILIANI, San Jose, CA (US); Sandip NIYOGI, Oakland, CA (US); Rene GEORGE, Redwood City, CA (US)

(21) Appl. No.: 18/674,683

(22) Filed: May 24, 2024

(51) Int. Cl. H01J 37/32; C23C 16/40; C23C 16/50; H01L 21/02

(52) U.S. Cl. CPC H01J 37/32449; C23C 16/401; C23C 16/50; H01L 21/02164; H01L 21/02274; H01J 2237/332

(57) ABSTRACT

Embodiments of the present disclosure generally include apparatus and methods thereof of processing a substrate. The methods include receiving a substrate in a processing volume of a processing chamber. The processing volume is bounded by one or more interior side walls. A barrier layer is formed over a surface of the substrate by introducing at least a first radical to the processing volume using a plasma source. An oxide layer is formed on the barrier layer by introducing a combination of the first radical and a second radical to the processing volume using the plasma source. The combination of the first radical and the second radical includes a first ratio of the first radical to the second radical, in which the first ratio can include a ratio of about 95:5 of the first radical to the second radical to about 40:60 of the first radical to the second radical.

### BACKGROUND

### Field

Embodiments of the present disclosure generally relate to plasma processing equipment and related methods, and more specifically to bilayer plasma oxidation processes.

### Description of the Related Art

Plasma processing techniques are used for deposition, etching, resist removal, and other processing of substrates (e.g., semiconductor substrates). The plasma processing techniques can include deposition and growth of oxide films and/or or polysilicon films on a substrate. When a plasma processing technique utilizes reactants, e.g., oxygen and/or hydrogen, to improve the conformity of the oxide films or polysilicon films, defects and/or impurities can form in one or more remaining layers, e.g., the oxide film or the polysilicon film. Unfortunately, the defects and/or impurities in the one or more remaining layers, e.g., the oxide film or the polysilicon film, cannot be removed from the films once imparted, thereby leading to an increase in the surface roughness as well as a reduction in the mechanical and electrical properties of the films.

Therefore, there is a need for improved equipment and related plasma processing techniques.

### SUMMARY

Embodiments of the present disclosure generally include methods of processing a substrate. The methods include receiving a substrate in a processing volume of a processing chamber. The processing volume is bounded by one or more interior side walls. A barrier layer is formed over a surface of the substrate by introducing at least a first radical to the processing volume using a plasma source. An oxide layer is formed on the barrier layer by introducing a combination of the first radical and a second radical to the processing volume using the plasma source. The combination of the first radical and the second radical includes a first ratio of the first radical to the second radical, in which the first ratio can include a ratio of about 95:5 of the first radical to the second radical to about 40:60 of the first radical to the second radical.

Embodiments of the present disclosure also generally include substrates. The substrates include a silicon sub-layer. An oxide sub-layer is disposed over the silicon sub-layer. A polysilicon sub-layer is disposed over the oxide sub-layer. A barrier layer is disposed over the polysilicon sub-layer. The barrier includes a barrier thickness of about 5 Å to about 30 Å. An oxide layer is disposed over the barrier layer. The oxide layer includes an oxide thickness of about 50 Å to about 80 Å.

Embodiments of the present disclosure also generally include plasma processing apparatus. The plasma processing apparatus includes a processing chamber defining a processing volume, a plasma source, and a controller. The controller is configured to receive a substrate in the processing volume. A barrier layer is formed over a surface of the substrate by introducing at least a first radical to the processing volume using the plasma source. An oxide layer is formed on the barrier layer by introducing a combination of the first radical and a second radical to the processing volume using the plasma source. The combination of the first radical and the second radical includes a first ratio of the first radical to the second radical, in which the first ratio can include a ratio of about 95:5 of the first radical to the second radical to about 40:60 of the first radical to the second radical.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and as the disclosure may admit to other equally effective embodiments.

FIG. 1A is a schematic diagram of a plasma processing apparatus with a grid suspended from a grid support, according to some embodiments of the present disclosure.

FIG. 1B is a schematic diagram of the plasma processing apparatus of FIG. 1A with a grid suspended from a grid support at a different spacing from the substrate support, according to some embodiments of the present disclosure.

FIG. 2 is an isometric view of the grid and grid support of FIGS. 1A and 1B, according to some embodiments of the present disclosure.

FIG. 3 is a flow diagram illustrating a method of forming an oxide layer on a barrier layer, according to some embodiments of the present disclosure.

FIGS. 4A-4C are schematic diagrams of a substrate corresponding to the method of forming an oxide layer on a barrier layer, according to some embodiments of the present disclosure.

FIG. 5 is a diagrammatic representation of various substrates processed according to the methods described herein, according to some embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to bilayer plasma oxidation processes. The bilayer plasma oxidation processes can provide a barrier layer that is deposited over a polysilicon film, in which the barrier layer can prevent and/or reduce hydrogen radicals from diffusing into the polysilicon layer and reacting with an amorphous Si—H bond, thereby reducing and/or preventing the formation of blisters or hydrogen gas (H₂) pockets in the film. The barrier layer can be deposited over the polysilicon film, in which an oxide film may be deposited over the barrier layer. The oxide film may include enhanced conformality due to the barrier layer preventing the diffusion of the hydrogen radicals into the polysilicon layer. Additionally, the bilayer plasma oxidation processes can provide enhanced step coverage with reduced and/or no defects, thereby reducing surface roughness and increasing the mechanical and electrical properties of the films. Moreover, the bilayer plasma oxidation processes can provide enhanced deposition rates with enhanced film quality, thereby increasing throughput and reducing manufacturing costs.

Aspects of the present disclosure are discussed with reference to a “substrate” for purposes of illustration and discussion. Those of ordinary skill in the art, using the disclosures provided herein, will understand that the example aspects of the present disclosure can be used in association with any suitable semiconductor substrate, semiconductor wafer, or other suitable substrate. A “substrate support” refers to any structure that can be used to support a substrate.

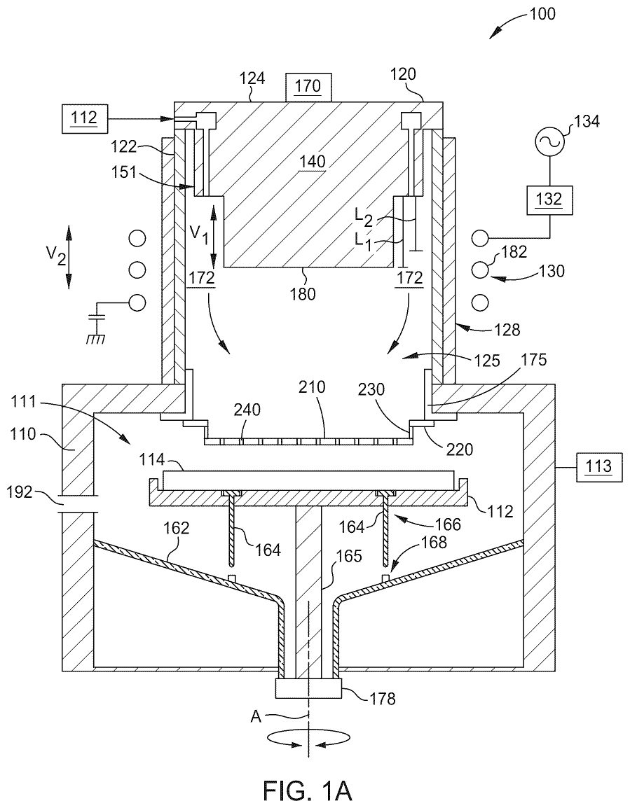

FIG. 1A is an exemplary plasma processing apparatus 100 with a grid 210 suspended from a grid support 220. The plasma processing apparatus 100 includes a processing chamber 110 and a plasma source 120 (e.g., a remote plasma source) coupled with the processing chamber 110. The processing chamber 110 includes a processing volume 111. A substrate support 112 operable to hold a substrate 114 is disposed in the processing volume 111. In some embodiments, the substrate has a thickness that is less than 1 mm. The substrate support 112 can be proximate one or more heat sources such as lamps or resistive heaters that provide heat to a substrate during processing of the substrate in the process chamber 110. Heat can be provided using any suitable heat source, such as one or more lamps, such as one or more rapid thermal processing lamps, or via a heated pedestal (e.g., a pedestal having resistive heating elements embedded therein or coupled thereto).

A controller 113 is coupled to the processing chamber 110, and may be used to control chamber processes described herein. The substrate support 112 is disposed underneath the grid 210. In some embodiments, the substrate support 112 is coupled with a shaft 165. The shaft is connected to an actuator 178 that provides rotational movement of the shaft and substrate support (about an axis). The actuator may additionally or alternatively provide height adjustment of the shaft 165 during processing.

The substrate support 112 includes lift pin holes 166 disposed therein. The lift pin holes 166 are sized to accommodate a lift pin 164 for lifting of the substrate 114 from the substrate support 112 either before or after a substrate process is performed. The lift pins 164 may rest on lift pin stops 168 when the substrate 114 is lowered from a processing position to a transfer position.

A plasma can be generated in plasma source 120 (e.g., in a plasma generation region) by induction coil 130, and plasma flows from the plasma source 120 to the surface of substrate 114 through holes 240 provided in the grid 210 that separates the plasma source 120 from the processing chamber 110 (a downstream region).

The plasma source 120 includes a dielectric sidewall 122 and a top cover 124. The dielectric sidewall 122 and top cover 124, integrated with a gas injection insert 140, define a plasma source interior 125. Dielectric sidewall 122 can include any suitable dielectric material, such as quartz. An induction coil 130 is disposed proximate (e.g., adjacent) the dielectric sidewall 122 about the plasma source 120. The induction coil 130 is coupled to an RF power generator 134 through any suitable matching network 132. Feed gases are introduced to the plasma source interior from a gas supply 150. When the induction coil 130 is energized with RF power from the RF power generator 134, a plasma is generated in the plasma source 120. In some embodiments, RF power is provided to induction coil 130 at about 1 kW to about 15 kW, such as about 3 kW to about 10 kW. Induction coil 130 may ignite and sustain a plasma in a wide pressure and flow range. In some embodiments, the plasma processing apparatus 100 includes a grounded Faraday shield 128 to reduce capacitive coupling of the induction coil 130 to the plasma.

A gas injection insert 140 may be disposed in the plasma source interior 125. A plurality of gas injection channels 151 provide the process gas to the plasma source interior 125 through an active zone 172, where, due to enhanced confinement of hot electrons, a reaction between hot electrons and the feed gas occurs. An enhanced electron confinement region or an active zone 172 is defined by sidewalls of gas injection insert and the vacuum tube in radial direction and by an edge of a bottom surface 180 of the insert from the bottom in vertical direction. The active zone 172 provides an electron confinement region within the plasma source interior 125 for efficient plasma generation and sustaining. The gas injection channels 151 prevents plasma spreading from the chamber interior into the gas injection channel 151. The gas injection channels 151 can be about 1 mm in diameter or greater, such as about 10 mm or greater, such as about 1 mm to about 10 mm. The gas injection insert 140 forces the process gas to be passed through the active zone 172 where plasma is formed.

In some embodiments, which can be combined with other embodiments, the gas injection insert 140 can be made from a metal, such as an aluminum material, with a coating configured to reduce surface recombination. Alternatively, the gas injection insert 140 can be a dielectric material, such as a quartz material, or an electrically insulating material.

In some embodiments, which can be combiend with other embodiments, a coil has a short transition region near the leads, and the remainder of the coil turns are parallel to the bottom surface 180, in other embodiments, a coil is helical, but one can always define the top and the bootom turn of the coil. In some embodiments, a coil can have 2-5 turns.

In some embodiments, an actuator 170 is coupled to gas injection insert 140 to adjust a position of the bottom surface 180 such that a portion of the gas injection insert 140 having a first length (L₁) is adjusted to a second length (L₂). Actuator 170 can be any suitable actuator, for example, a motor, electric motor, stepper motor, or pneumatic actuator. Additionally or alternatively, the gas injection insert 140 can be coupled to an actuator (such as actuator 170), and actuator 170 is configured to move the entirety of gas injection insert 140 vertically (e.g., along a vertical direction V₁ relative to plasma source 120).

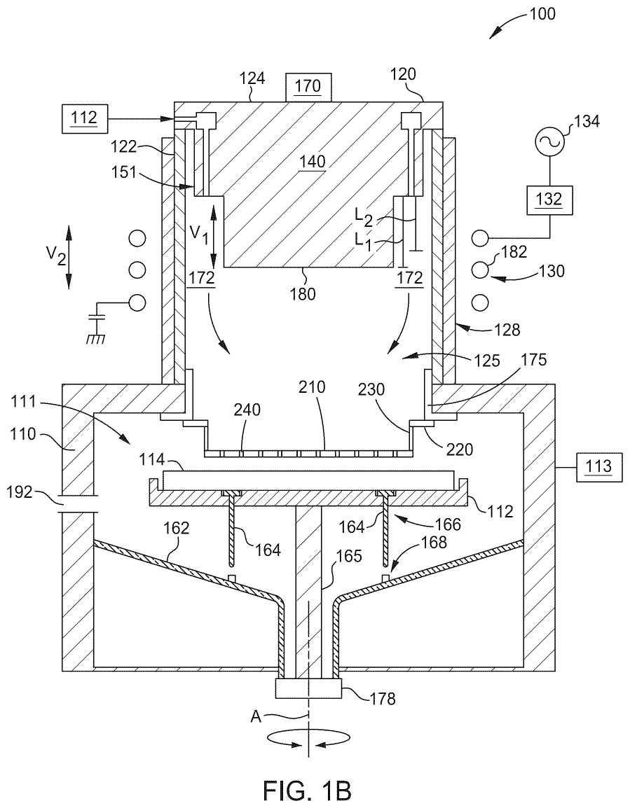

A process liner 175, optional, is disposed on the processing chamber 110 and the plasma source 120 where the plasma source 120 and the processing chamber 110 are coupled together. The process liner 175 prevents process gases and plasma from escaping through where the process chamber 110 and the plasma source 120 are coupled. The grid support 220 is coupled to the processing chamber 110. In some embodiments, the grid support 220 is coupled to the process liner 175, which is coupled to the processing chamber 110. In other embodiments, the grid support 220 is coupled directly to the process chamber 110. The grid 210 is coupled to the grid support 220. The grid 210 is disposed above the substrate support 112. In FIG. 1A, the grid 210 is suspended below the grid support 220. The grid 210 is coupled to the grid support 220 using a plurality of vertical supports 230. The vertical supports 230 are coupled to the grid 210 and the grid support 220. The grid 210, grid support 220, and vertical supports 230 form a grid assembly 200. As shown in FIG. 1A in some embodiments, two vertical supports 230 are used to couple the grid 210 to the grid support 220. In other embodiments, more vertical supports 230 are used, such as three vertical supports 230 in FIG. 2. In yet other embodiments, which may be combined with embodiments herein, the grid 210 is omitted entirely.

The grid 210 includes a plurality of holes 240. The holes 240 are disposed through the grid 210 (e.g., holes 240 traverse the thickness of the grid 210). One or more outer openings 250 (shown in FIG. 2) are defined by the grid 210, the grid support 220, and the vertical supports 230. The grid 210 is configured to separate the processing chamber 110 area from the plasma source 120.

The grid 210 can control the flow of plasma through the holes 240 and the outer openings 250. The plasma is configured to flow from the plasma source 120 through the grid 210 and outer opening 250 to the substrate support. The plasma source 120 may generate plasma charged particles (ions and electrons), which recombine on the grid 210, so that only neutral plasma species can pass through the grid 210 into the processing chamber 110. The plurality of holes in the bottom section of the grid 210 may have different patterns and sizes, as described in FIG. 2. The one or more outer openings 250 may have different sizes as shown in FIG. 2.

In some embodiments, the grid 210 is formed of aluminum, anodized aluminum, quartz, aluminum nitride, aluminum oxide, tantalum, tantalum nitride, titanium, titanium nitride, or combination(s) thereof. For example, AlN can be beneficial for flux of nitrogen radicals, whereas conventional grids are more prone to nitrogen radical recombination. Similarly, aluminum oxide can provide flux of oxygen or hydrogen radicals, whereas conventional grids are more prone to their recombination. In some embodiments, the grid 210 has a thickness of about 0.1 mm to about 20 mm, such as about 0.5 mm to 10 mm, such as 1 mm to 5 mm, which defines the hole length. A ratio of the grid thickness (length) to the average diameter of the plurality of holes may be greater than about 0.004, such as about 0.04 to about 7.9. In some embodiments, the grid has a diameter of about 50 mm to about 500 mm, such as about 100 mm to 400 mm, such as about 100 mm to about 250 mm. The diameter of the grid is configured such that a substrate 114 atop the substrate support has a diameter that is greater than the diameter of the grid.

The plasma source 120 is configured to flow plasma towards the grid 210. A portion of the plasma flows through the holes 240 of the grid 210. Another portion of the plasma flows through the outer openings 250 between the grid 210 and the grid support 220. After flowing through the holes 240 and the outer openings 250, the plasma flows to the substrate support 112. The plasma is used to treat the substrate 114. The portion of the plasma that passes through the holes 240 primarily treats a central region of the substrate 114. The portion of plasma that passes through the outer openings 250 primarily treats the edges of the substrate 114. As stated above, the grid 210 acts as a flow manager of the plasma. The grid 210 prevents recombination of plasma on walls of the processing chamber 110.

Recombination of the plasma on the walls limits the plasma that reaches the edges of the substrate 114, causing non-uniform distribution of the plasma across the substrate 114. However, implementing only a grid 210 may not produce uniform distribution of plasma on and/or near the edges of the substrate 114. For example, plasma that passes through the holes 240 of the grid may still be focused near the center of the substrate 114. Accordingly, plasma may be directed to flow directly on the edges of the substrate to ensure the edges are uniformly covered by plasma. Plasma flowing through the outer openings 250 between the grid 210 and the grid support 220 promotes the edges to receive uniform distribution of the plasma. The portion of the plasma that flows through the outer openings 250 will contact the substrate 114 on the edges. By having the plasma contact the edges directly, the plasma will be more uniformly distributed.

An exhaust port 192 is coupled with a sidewall of process chamber 110. In some embodiments, the exhaust port 192 may be coupled with a bottom wall of process chamber 110 to provide azimuthal independence.

The plurality of vertical supports 230 can be used to couple the grid 210 to the grid support 220. In FIG. 2, three vertical supports 230 are shown, a first vertical support 231, a second vertical support 232, and a third vertical support 233. In some embodiments, a different number of vertical supports 230 is implemented. The vertical supports 230 may be mechanically adjusted to change the distance 215 between the grid 210 and the grid support 220. In some embodiments, the distance 215 is about 1 inch to about 3 inches. The distance 215 is directly related to the distance between the grid 210 and the substrate support 112. The distance between the grid 210 and substrate support 112 affects the distribution of the plasma around the edges of the substrate. The distance between the grid 210 and substrate support 112 creates shadowing effects. When the distance 215 is smaller, the outer openings 250 are smaller, and less plasma reaches the edges of the substrate 114. When the distance 215 is larger, the grid 210 is closer to the substrate support 112, and the shadowing effects occur. Shadowing effects refer to grid assembly 200 casting a shadow on the treated substrate 114 by affecting the distribution of plasma on the substrate 114. For example, when the grid 210 is closer to the substrate support 112, the hole 240 pattern of the grid 210 may be visible on the surface of the substrate 114 because the plasma does not contact the substrate in the location directly below the structure of the hole 240. Since the plasma expands as it travels through the processing chamber 110, the hole diameter 241 is selected based on the distance 215.

The grid 210 is circular in shape and has a circumference 211 and a diameter 212. The grid support 220 is ring shaped and has a radial length 221, an inner circumference 222, and an outer circumference 223. In some embodiments, the vertical supports 230 are coupled to the grid 210 on the circumference 211 of the grid 210. On the opposite end, the vertical supports 230 are coupled to the grid support 220 on the inner circumference 222 of the grid support 220.

The outer openings 250 are shown in FIG. 2. Each outer opening 250 is defined between a portion of the circumference 211 of the grid 210, a portion of the inner circumference 222 of the grid support 220, and the vertical supports 230. In FIG. 2, three outer openings 250 are shown, a first outer opening 251, a second outer opening 252, and a third outer opening 253. The first outer opening 251 is defined by a first portion of the circumference 211 of the grid 210, a first portion of the inner circumference 222 of the grid support 220, the first vertical support 231, and the second vertical support 232. The second outer opening 252 is defined by a second portion of the circumference 211 of the grid 210, a second portion of the inner circumference 222 of the grid support 220, the second vertical support 232, and the third vertical support 233. The third outer opening 253 is defined by a third portion of the circumference 211 of the grid 210, a third portion of the inner circumference 222 of the grid support 220, the third vertical support 233, and the first vertical support 231.

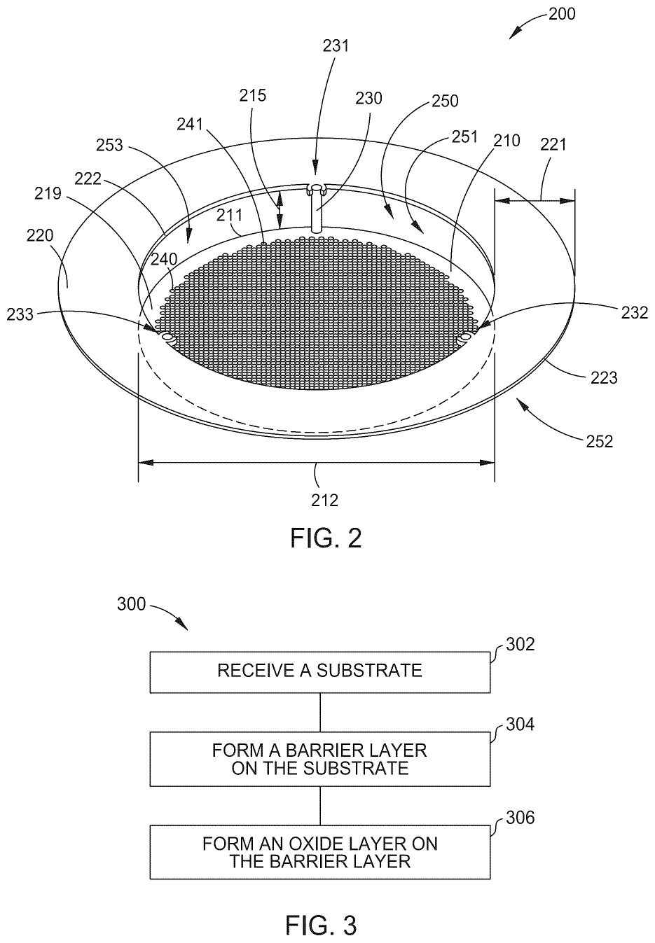

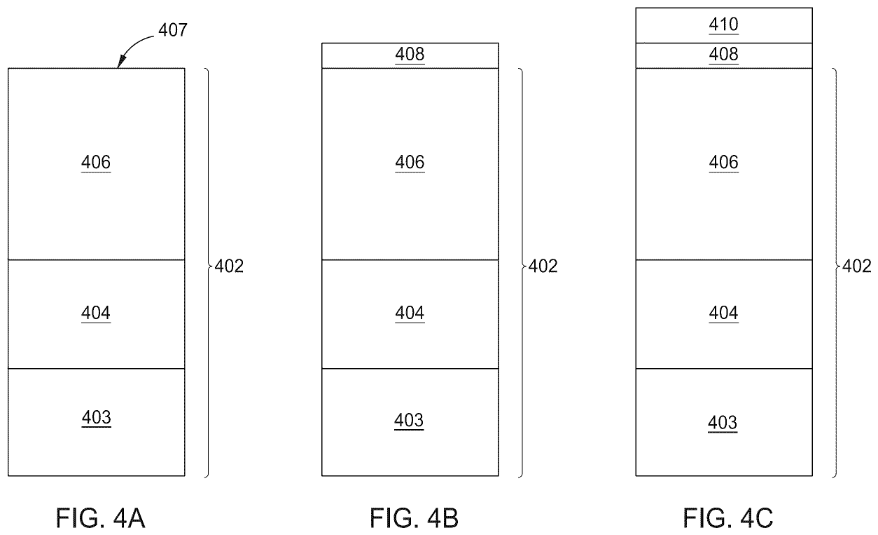

FIG. 3 shows a flow diagram illustrating a method of forming an oxide layer on a barrier layer. In some embodiments, the methods provided herein can provide for a deposition process that can oxidize a structure, e.g., a vertical structure and/or a horizontal trench, in a gate all round transistor, e.g., 3D NAND, 3D DRAM and CFET device. At operation a substrate 402 is received, the substrate 402 can include a silicon sub-layer 403, as shown in FIG. 4. The silicon sub-layer 403 can include amorphous silicon. The substrate 402 can include an oxide sub-layer 404 disposed over the silicon sub-layer 403. The oxide sub-layer 404 can include a silicon oxide. The substrate can include a polysilicon sub-layer 406. In some embodiments, each of the silicon sub-layer 403, the oxide sub-layer 404, and the polysilicon sub-layer 406 can include a thickness of about 10 Å to about 150 Å, e.g., about 10 Å to about 120 Å, about 10 Å to about 100 Å, or about 10 Å to about 70 Å.

At operation 304, a barrier layer 408 is deposited over the substrate 402, as shown in FIG. 4. The barrier layer 408 includes an oxide layer, e.g., a silicon oxide. In some embodiments, the barrier layer 408 includes a barrier thickness of about 5 Å to about 30 Å, e.g., about 5 Å to about 25 Å, about 10 Å to about 25 Å, about 10 Å to about 20 Å, or about 10 Å to about 15 Å. In some embodiments, the barrier layer 408 can be formed by contacting the surface of the substrate 114 with a first radical, e.g., an oxygen radical, in order to oxidize an upper portion 407, e.g., an upper surface, of the polysilicon sub-layer 406. For example, the first radical can include an oxygen radical.

When utilizing chambers disclosed herein, the first radical is formed in the active zone 172 of the plasma source interior 125. For example, the gas injection insert 140 can introduce a first gas including oxygen to form the first radical. In some embodiments, the first gas can be introduced to the active zone 172 of the plasma source interior 125 at a first gas flow rate of about 1,000 standard cubic centimeters per minute (sccm) to about 10,000 sccm, e.g., about 1,000 sccm to about 9,500 sccm, about 1,500 to about 9,500 sccm, about 1,500 sccm to about 8,500 sccm, about 4,000 sccm to about 8,500 sccm, or about 6,000 sccm to about 8,000 sccm. In some embodiments, the first radical can be introduced for a period of time of about 10 seconds (s) to about 500 s, e.g., about 60 s to about 400 s, about 90 s to about 300 s, or about 120 s to about 300 s.

The barrier layer 408 is formed while maintaining a pressure of about 1 Torr to about 20 Torr, e.g., about 1 Torr to about 10 Torr, about 1 Torr to about 8 Torr, or about 1 Torr to about 5 Torr. In some embodiments, the barrier layer 408 can be formed while maintaining a temperature of about 250° C. to about 700° C., e.g., about 250° C. to about 650° C., about 400° C. to about 650° C., or about 550° C. to about 650° C. In some embodiments, the barrier layer 408 can be formed while operating the plasma source at a power of about 5 kW to about 10 kW, e.g., about 5 kW to about 8 kw, about 6 kW to about 8 kW, or about 7 kW to about 8 kW.

In some embodiments which can be combined with other embodiments, the barrier layer 408 can be formed by introducing a second radical e.g., a hydroxide radical, an argon radical, a hydrogen radical, an nitrogen radical or a combination thereof. For example, the first radical can include a hydrogen radical. In some embodiments, the second radical can be formed in the active zone 172 of the plasma source interior 125. For example, the gas injection insert 140 can introduce a second gas including hydrogen, argon, nitrogen, and/or helium to form the second radical. In some embodiments, the second gas can be introduced to the active zone 172 of the plasma source interior 125 at a flow rate of about 0 sccm to about 4000 sccm, e.g., about 0 sccm to about 2,000 sccm, about 0 sccm to about 1,500 sccm, about 0 sccm to about 500 sccm, or about 0 sccm to about 100 sccm. In some embodiments, the second radical can be introduced for a period of time of about 10 seconds (s) to about 500 s, e.g., about 60 s to about 400 s, about 90 s to about 300 s, or about 120 s to about 300 s. In one specific example, the barrier layer is formed by providing both hydrogen and oxygen radicals.

A carrier gas, e.g., argon, nitrogen, helium, or a combination thereof, can be introduced to the active zone 172 of the plasma source interior 125 at a flow rate of about 5,000 sccm to about 10,000 sccm, e.g., about 5,000 sccm to about 9,500 sccm, about 5,500 to about 9,500 sccm, about 5,500 sccm to about 8,500 sccm, about 6,000 sccm to about 8,500 sccm, or about 7,000 sccm to about 8,000 sccm. In some embodiments, the carrier gas can be introduced for a period of time of about 10 seconds (s) to about 500 s, e.g., about 60 s to about 400 s, about 90 s to about 300 s, or about 120 s to about 300 s. The carrier gas may facilitate flow of other process gases.

A flow ratio of the first radical to the second radical for forming the barrier layer can include a ratio weight percent (wt %) of about 90:10 of the first radical to the second radical to about 100:0 of the first radical to the second radical. For example, the barrier ratio can include a ratio wt % of about 90:10, about 91:9, about 92:8, about 93:7, about 94:6, about 95:5, about 96:4, about 97:3, about 98:2, about 99:1, or about 100:0 of the first radical to the second radical. Without being bound by theory, a flow ratio for forming the barrier layer can be from about 90:10 of the first radical to the second radical to about 100:0 of the first radical to the second radical can allow for the formation of a barrier layer while preventing hydrogen radical diffusion through the polysilicon sub-layer 406, thereby reducing surface roughness due to the reduction of impurities and/or hydrogen gas pockets from forming in the polysilicon layer.

At operation 306, an oxide layer 410 is deposited over the barrier layer 408, as shown in FIG. 4. The oxide layer 410 includes an oxide layer, e.g., a silicon oxide. In some embodiments, the oxide layer 410 includes an oxide thickness of about 50 Å to about 80 Å, e.g., about 50 Å to about 75 Å, about 60 Å to about 75 Å, about 60 Å to about 70 Å, or about 65 Å to about 70 Å. In some embodiments, the oxide layer 410 can be formed by contacting the surface of the barrier layer 408 with the first radical, e.g., an oxygen radical, and the second radical, e.g., a hydroxide radical, an argon radical, a hydrogen radical, an nitrogen radical or a combination thereof. For example, the first radical can include an oxygen radical and the second radical can include a hydrogen radical.

A flow ratio of the first radical to the second radical for forming the oxide layer 410 can include a ratio wt % of about 95:5 of the first radical to the second radical to about 40:60 of the first radical to the second radical. For example, the flow ratio for forming the oxide layer 410 can include a ratio of about 95:5, about 90:10, about 85:15, about 80:20, about 75:25, about 70:30, about 65:35, about 60:40, about 55:45, about 50:50, about 45:55, or about 40:60 of the first radical to the second radical. Without being bound by theory, a flow ratio for forming the oxide layer 410 can including ratio of about 95:5 of the first radical to the second radical to about 40:60 of the first radical to the second radical can allow for enhanced step coverage of the oxide layer deposited on the barrier layer without forming one or more defects and/or impurities within the polysilicon sub-layer 406, thereby reducing surface roughness and increasing mechanical and electrical properties of the films. In some embodiments, a gradient in an oxide quality can exist between the oxide layer 410 and the barrier layer 408, in which the oxide quality can increase towards the oxide layer 410.

The first radical and the second radical can be formed in the active zone 172 of the plasma source interior 125. For example, the gas injection insert 140 can introduce a first gas including oxygen to form the first radical, and a second gas including hydrogen, argon, nitrogen, and/or helium to form the second radical. In some embodiments, the first gas and the second gas can be introduced to the active zone 172 of the plasma source interior 125 at a flow rate of about 100 sccm to about 10,000 sccm, e.g., about 1,000 sccm to about 9,500 sccm, about 1,500 to about 9,500 sccm, about 1,500 sccm to about 8,500 sccm, about 4,000 sccm to about 8,500 sccm, or about 6,000 sccm to about 8,000 sccm. In some embodiments, the first radical and the second radical can be introduced for a period of time of about 10 seconds (s) to about 500 s, e.g., about 60 s to about 400 s, about 90 s to about 300 s, or about 120 s to about 300 s.

The oxide layer 410 is formed while maintaining a pressure of about 1 Torr to about 20 Torr, e.g., about 1 Torr to about 10 Torr, about 1 Torr to about 8 Torr, or about 1 Torr to about 5 Torr. In some embodiments, the oxide layer 410 can be formed while maintaining a temperature of about 250° C. to about 700° C., e.g., about 250° C. to about 650° C., about 400° C. to about 650° C., or about 550° C. to about 650° C. The oxide layer 410 can be formed while operating the plasma source at a power of about 5 kW to about 10 kW, e.g., about 5 kW to about 8 kw, about 6 kW to about 8 kW, or about 7 kW to about 8 kW.

A carrier gas, e.g., argon, nitrogen, helium, or a combination thereof, can be introduced to the active zone 172 of the plasma source interior 125 at a flow rate of about 5,000 sccm to about 10,000 sccm, e.g., about 5,000 sccm to about 9,500 sccm, about 5,500 to about 9,500 sccm, about 5,500 sccm to about 8,500 sccm, about 6,000 sccm to about 8,500 sccm, or about 7,000 sccm to about 8,000 sccm. In some embodiments, the carrier gas can be introduced for a period of time of about 10 seconds (s) to about 500 s, e.g., about 60 s to about 400 s, about 90 s to about 300 s, or about 120 s to about 300 s.

### EXAMPLES

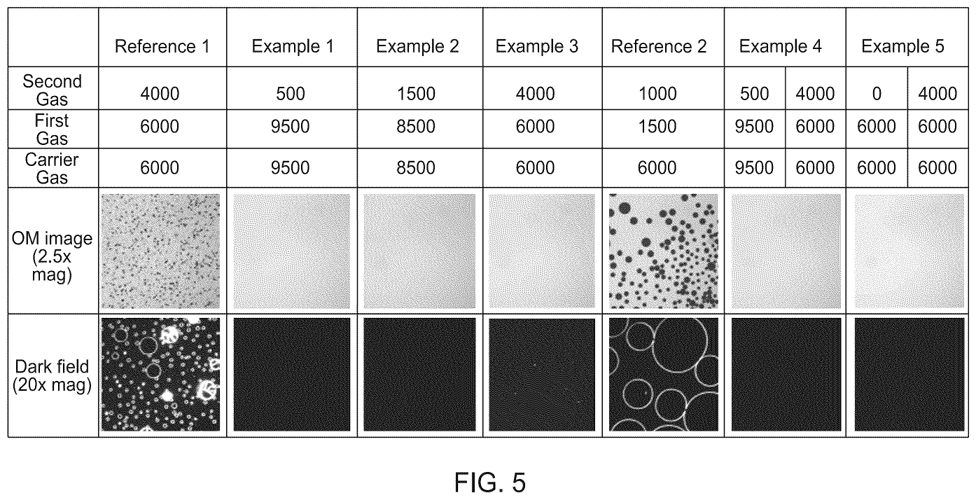

As shown in FIG. 5, a first substrate (Reference 1) a second substrate (Example 1), a third substrate (Example 2), a fourth substrate (Example 3), a fifth substrate (Reference 2), a sixth substrate (Example 4), and a seventh substrate (Example 5), were prepared by flowing about 1,500 sccm to about 9,5000 sccm of a first gas, e.g., oxygen, about 0 sccm to about 4,000 sccm of a second gas, e.g., hydrogen, and about 6,000 sccm to about 9,500 sccm of a carrier gas, e.g., argon into an active zone of the apparatus at a temperature of about 650° C., a pressure of about 3 Torr, a plasma power of about 8 kW, and a period of time of about 60 s to about 300 s. The substrates were imaged using an optical microscope at 2.5× magnification and using dark field microscopy at 20× magnification. Examples 1, 2, and 3 resulted in a low surface roughness with reduced oxide conformality compared to Reference 1 and Reference 2. Example 4 and Example 5 resulted in a low surface roughness and an increased oxide conformality compared to Reference 1 and Reference 2, in which the low surface roughness and increased oxide conformality resulted due to the use of a first process having a ratio of about 95:5 or 100:0 of the first gas to the second gas, respectively, and a second process having a ratio of 60:40. Other ranges and process values disclosed herein provide similar benefits.

Overall, the bilayer plasma oxidation processes can provide an barrier layer that is deposited over a polysilicon film, in which the barrier layer can prevent and/or reduce hydrogen radicals from diffusing into the polysilicon layer and reacting with an amorphous Si—H bond, thereby reducing and/or preventing the formation of blisters or hydrogen gas (H₂) pockets in the film. The barrier layer can be deposited over the polysilicon film, in which an oxide film may be deposited over the barrier layer. The oxide film may include enhanced conformality due to the barrier layer preventing the diffusion of the hydrogen radicals into the polysilicon layer. Additionally, the bilayer plasma oxidation processes can provide enhanced step coverage with reduced and/or no defects, thereby reducing surface roughness and increasing the mechanical and electrical properties of the films. Moreover, the bilayer plasma oxidation processes can provide enhanced deposition rates with enhanced film quality, thereby increasing throughput and reducing manufacturing costs.

While the foregoing is directed to embodiments of the present disclosure, other and further embodiments of the disclosure may be devised without departing from the basic scope thereof.

What is claimed is:

1. A method of processing a substrate, comprising:
receiving a substrate in a processing volume of a processing chamber, the processing volume bounded by one or more interior side walls;
forming a barrier layer over a surface of the substrate by introducing at least a first radical to the processing volume using a plasma source; and
forming an oxide layer on the barrier layer by introducing a combination of the first radical and a second radical to the processing volume using the plasma source, wherein the combination of the first radical and the second radical comprises a first ratio of the first radical to the second radical, wherein the first ratio comprises a ratio of about 95:5 of the first radical to the second radical to about 40:60 of the first radical to the second radical.

2. The method of claim 1, wherein each of the first radical and the second radical independently comprise an oxygen radical, a hydrogen radical, a nitrogen radical, an argon radical, or a helium radical.

3. The method of claim 2, wherein the first radical comprises the oxygen radical.

4. The method of claim 2, wherein the second radical comprises the hydrogen radical.

5. The method of claim 1, wherein forming the barrier layer comprises introducing the combination of the first radical and the second radical to the processing volume.

6. The method of claim 5, wherein the combination of the first radical to the second radical can include a second ratio of about 90:10 of the first radical to the second radical to about 100:0 of the first radical to the second radical.

7. The method of claim 6, wherein forming the barrier layer by introducing the at least a first radical to the processing volume comprises introducing a first gas at a first gas flow rate of about 1,000 (standard cubic centimeters per minute) sccm to about 10,000 sccm, and introducing a second gas at a second gas flow rate of about 0 sccm to about 4000 sccm.

8. The method of claim 7, wherein forming the oxide layer by introducing the first radical and the second radical to the processing volume comprises introducing the first gas and the second gas at a flow rate of about 100 sccm to about 10,000 sccm.

9. A substrate, comprising:
a silicon sub-layer;
an oxide sub-layer disposed over the silicon sub-layer;
a polysilicon sub-layer disposed over the oxide sub-layer;
a barrier layer disposed over the polysilicon sub-layer, the barrier layer comprising a barrier thickness of about 5 Å to about 30 Å; and
an oxide layer disposed over the barrier layer, the oxide layer comprising an oxide thickness of about 50 Å to about 80 Å.

10. The substrate of claim 9, wherein the oxide sub-layer comprises a silicon oxide.

11. The substrate of claim 9, wherein the silicon sub-layer comprises amorphous silicon.

12. The substrate of claim 9, wherein the barrier layer comprises silicon oxide.

13. A plasma processing apparatus, the plasma processing apparatus comprising:
a processing chamber defining a processing volume;
a plasma source; and
a controller, the controller configured to
receive a substrate in the processing volume,
form a barrier layer over a surface of the substrate by introducing at least a first radical to the processing volume using the plasma source, and
form an oxide layer on the barrier layer by introducing a combination of the first radical and a second radical to the processing volume using the plasma source, wherein the combination of the first radical and the second radical comprises a first ratio of the first radical to the second radical, wherein the first ratio comprises a ratio of about 95:5 of the first radical to the second radical to about 40:60 of the first radical to the second radical.

14. The plasma processing apparatus of claim 13, wherein each of the first radical and the second radical independently comprise an oxygen radical, a hydrogen radical, a nitrogen radical, an argon radical, or a helium radical.

15. The plasma processing apparatus of claim 14, wherein the first radical comprises the oxygen radical.

16. The plasma processing apparatus of claim 14, wherein the second radical comprises the hydrogen radical.

17. The plasma processing apparatus of claim 13, wherein the controller is further configured to deposit the barrier layer by introducing the combination of the first radical and the second radical to the processing volume.

18. The plasma processing apparatus of claim 17, wherein the combination of the first radical to the second radical can include a second ratio of about 90:10 of the first radical to the second radical to about 100:0 of the first radical to the second radical.

19. The plasma processing apparatus of claim 18, wherein the controller is further configured to deposit the barrier layer by introducing a first gas at a first gas flow rate of about 1,000 sccm to about 10,000 sccm, and introducing a second gas at a second gas flow rate of about 0 sccm to about 4000 sccm.

20. The plasma processing apparatus of claim 19, wherein the controller is further configured to form the oxide layer by introducing the first gas and the second gas at a flow rate of about 100 sccm to about 10,000 sccm.
